(19) United States
(12) Patent Application Publication
(10) Pub. No.: US 2026/0045761 A1
(43) Pub. Date: Feb. 12, 2026

(54) Method for Adjusting a Diode Current of a Laser System

(71) Applicant: Robert Bosch GmbH, Stuttgart (DE)

(72) Inventors: Joern Hoffarth, Reutlingen (DE); David Copeto, Ludwigsburg (DE); Stefan Noe, Stuttgart (DE)

(21) Appl. No.: 19/289,054

(22) Filed: Aug. 3, 2025

(30) Foreign Application Priority Data
Aug. 7, 2024 (DE) 10 2024 207 475.6

(51) Int. Cl. H01S 5/00; G01C 3/02; H01S 5/042; H01S 5/0687

(52) U.S. Cl. CPC H01S 5/0085; G01C 3/02; H01S 5/0427; H01S 5/0687

(57) ABSTRACT

A method for adjusting a diode current of a laser system includes (i) determining a change in an integral part of a control signal of the laser system in an unmodulated laser operation, and (ii) adjusting the diode current of the laser system in a modulated laser operation based on the determined change in the integral part, wherein the modulated laser operation differs from the unmodulated laser operation in that intensity modulation is performed during light emission in the modulated laser operation. A computer program, an apparatus, and a storage medium for this purpose are also disclosed.

This application claims priority under 35 U.S.C. § 119 to application no. DE 10 2024 207 475.6, filed on Aug. 7, 2024 in Germany, the disclosure of which is incorporated herein by reference in its entirety.

The disclosure relates to a method for adjusting a diode current of a laser system. The disclosure further relates to a computer program, an apparatus, and a storage medium for this purpose.

### BACKGROUND

Precise control of a diode current in a laser system is critical for a variety of applications requiring accurate emission of laser light. In measurement technology, in particular in laser rangefinders, precise control of the diode current is essential to ensure the stability and precision of the light source. Inaccurately controlled diode current may result in fluctuations in laser power, significantly affecting measurement accuracy and reliability. In addition, the diode current directly affects the modulation properties of the laser that are essential for phase shift measurement in the time-of-flight (ToF) method. A constant and precise power supply not only ensures a stable light intensity but also a consistent wavelength and spectral purity of the emitted light. This is particularly important in challenging environments where temperature and power variations can occur. Therefore, the development of advanced technologies for precisely controlling the diode current in the laser system is a key concern to optimize the performance and accuracy of laser-based measuring devices and other optical systems.

### SUMMARY

The subject-matter of the disclosure is a method, a computer program, a device, and a computer-readable storage medium having the features set forth below. Further features and details of the disclosure will emerge from the description and the drawings. Features and details which are described in connection with the method according to the disclosure naturally also apply in connection with the computer program according to the disclosure, the apparatus according to the disclosure, and the computer-readable storage medium according to the disclosure, and vice versa in each case, so that a reciprocal reference is always possible with regard to the disclosure of the disclosure.

The subject matter of the disclosure is in particular a method for adjusting a diode current of a laser system, comprising the following steps, wherein the steps can be repeated and/or performed in a certain order. The diode current in the laser system is in particular the electrical current flowing through the semiconductor diode used to generate laser light. This current is in particular generated by applying a voltage to the diode, and flows through the active layer of the diode, consisting of a semiconductor material, such as gallium arsenide. The current stimulates the electrons in the active layer and so produces photons, which are then amplified by the laser cavity to generate the laser beam. The diode current is in particular an important parameter for controlling laser power and is controlled, for example, by electronic circuitry.

In a first step, preferably a change of an integral part of a control signal of the laser system is determined in an unmodulated laser operation.

For a pure integral controller (I-controller) in a laser system, the change in the integral part can be determined, for example, as follows. With a pure I-control, in particular only the integral part is used for control. The I-controller preferably corrects the control error by taking into account a sum of past errors.

The pure I-controller may be described by the equation

$$I ( t ) = {K}_{i} {\int }_{0}^{t} e ( τ ) d τ ,$$

wherein Kᵢ is the amplification of the I part and e(τ) is the control error at time t.

Subsequently, a model of the laser system and the pure I-controller may be created in a simulation environment (e.g., MATLAB/Simulink) to determine the change in the integral part. Thus, a behavior of the laser system with the I part can be simulated and further relevant data such as the control error e(τ) and an output variable of the system can be determined. The recorded data may then be analyzed. As an alternative to the simulation, the laser system may also be read during ongoing operation.

In a further step, the diode current of the laser system 1 is preferably adjusted in a modulated laser operation based on the determined change in the integral part. For this purpose, for example, the determined change in the integral part in the unmodulated laser operation can be added to an integral part in the modulated laser operation or offset against each other in a comparable manner.

The modulated laser operation particularly differs from the unmodulated laser operation in that intensity modulation is performed during light emission, particularly light emission by a laser or a laser diode of the laser system, in the modulated laser operation.

With the method according to the disclosure, power and stability of the laser in modulated laser operation may be optimized and adjusted more quickly. As a result, a measurement based on the emitted laser light can be performed advantageously more quickly and with a higher precision, for example in the context of a distance measurement.

It is also advantageous if, in the context of the disclosure, the adjustment is performed specifically for a modulation frequency used in the intensity modulation, by which the light emitted by a laser diode is intensity modulated, wherein the laser diode is operated by the diode current. It is thus possible that the diode current may be adjusted to the respective modulation frequency. As a result, an optimal level of performance and stability can be achieved for each intensity modulation.

A further advantage may be achieved in the context of the disclosure if intensity modulation is performed for at least two modulation frequencies and the adjustment is made specifically for the respective modulation frequency of the at least two modulation frequencies. It is thus possible for individual adjustments to the diode current to be made for different modulation frequencies. This may result in improved performance and accuracy of the laser system, in particular a laser rangefinder. Furthermore, a planned fault can already be compensated in advance, so that the fault particularly does not need to be adjusted for at all in the ideal case.

It may be advantageous in the context of the disclosure if the determination is performed on a device-specific basis for the laser system. The specific determination of the integral part as a function of the individual laser system may advantageously enable finer adjustment of the diode current and thus more precise control of the laser power in the modulated laser operation.

In addition, it is contemplated within the scope of the disclosure that the determination is performed repeatedly during operation of the laser system in order to dynamically determine the change in the integral part. This may have the advantage that an adjustment of the diode current to changed or changing operating parameters of the laser system, for example, but also to changing temperature or changing air pressure of an environment of the laser system, is possible. The modulated laser operation may thus be optimized in real time or at least continuously.

In another possibility, it can be provided that the adjusting comprises the following step:
determining an offset for an input value of a digital-analog converter of the laser system based on the determined change in the integral part,
adding the determined offset to a current input value of the digital-analog converter of the laser system to use it as the new input value for the digital-analog converter.
   As a result, the adjustment of the diode current can be precise and efficient. Determining the offset for the digital-analog converter allows in particular fine control of intensity modulation and thus improved adjustment to the performance and stability of the laser.

Furthermore, it is conceivable that the laser system is a laser rangefinder. As a result, the method may be used for adjusting the diode current in a laser rangefinder. The precise adjustment of the diode current allows a reliable and accurate measurement of the distance through the phase shift of the reflected light signal.

Another object of the disclosure is a computer program, in particular a computer program product, comprising commands which, when the computer program is executed by a computer, cause the computer to carry out the method according to the disclosure. The computer program according to the disclosure thus brings with it the same advantages as have been described in detail with reference to a method according to the disclosure.

The disclosure also relates to an apparatus for data processing which is configured so as to carry out the method according to the disclosure. The apparatus can be a computer, for example, that executes the computer program according to the disclosure. The computer can comprise at least one processor for executing the computer program. A non-volatile data memory can be provided as well, in which the computer program can be stored and from which the computer program can be read by the processor for execution. The device may also be an analog discrete electronic circuit or an integrated electronic circuit configured to perform the method according to the disclosure.

The disclosure can also relate to a computer-readable storage medium, which comprises the computer program according to the disclosure and/or commands that, when executed by a computer, prompt said computer program to carry out the method according to the disclosure. The storage medium is configured as a data memory such as a hard drive and/or a non-volatile memory and/or a memory card, for example. The storage medium can, for example, be integrated into the computer.

In addition, the method according to the disclosure can also be designed as a computer-implemented method. Alternatively or additionally, at least one of the disclosed method steps may be computer-implemented and/or performed automatically.

### BRIEF DESCRIPTION OF THE DRAWINGS

Further advantages, features, and details of the disclosure emerge from the following description, in which exemplary embodiments of the disclosure are described in detail with reference to the drawings. The features mentioned in the claims and in the description can each be essential to the disclosure individually or in any combination. The figures show:

FIG. 1 a schematic visualization of a method, a device, a storage medium, and a computer program according to exemplary embodiments of the disclosure,

FIG. 2 a schematic illustration of a laser system according to exemplary embodiments of the disclosure.

### DETAILED DESCRIPTION

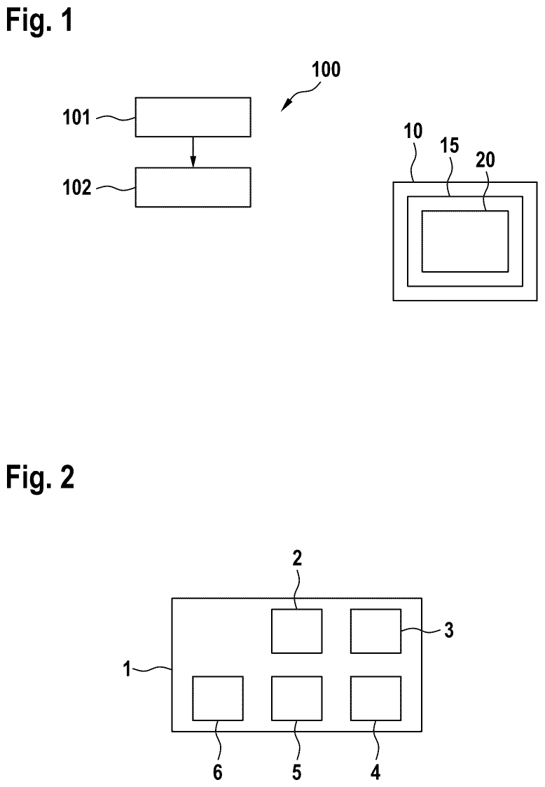

FIG. 1 schematically illustrates a method 100, a device 10, a storage medium 15, and a computer program 20 according to exemplary embodiments of the disclosure.

In particular, FIG. 1 shows an exemplary embodiment of a method 100 for adjusting a diode current of a laser system 1. In a first step 101, a change in an integral part of a control signal of the laser system 1 is determined in an unmodulated laser operation. In a second step 102, the diode current of the laser system 1 is adjusted in a modulated laser operation based on the determined change in the integral part. The modulated laser operation particularly differs from the unmodulated laser operation in that intensity modulation is performed during light emission in the modulated laser operation.

The method of the present disclosure relates to a laser system 1, and according to exemplary embodiments, in particular to a laser rangefinder that uses the indirect Time of Flight (iToF) measurement method. For this exemplary embodiment, reference is made to FIG. 2. For example, this laser rangefinder 1 operates by measuring a phase shift of a modulated light signal emitted by the laser rangefinder and reflected by a target object. The following is a description of how the Indirect Time of Flight (iToF) measurement works. First, a laser diode 3 in the laser rangefinder 1 can transmit intensity-modulated light, for example in the infrared or visible area, towards a target object. The modulation is in particular carried out with a sinusoidal or square wave. The intensity-modulated light subsequently strikes the target object and is reflected back to the laser rangefinder 1. A detector 4 in the measuring device can now receive the reflected light. Since the light takes a certain amount of time to travel the distance, there is a phase shift between the transmitted signal and the received signal. This phase shift between the transmitted signal and the received signal may then be measured. This phase shift is in particular proportional to the distance of the light traveled. The distance may then be calculated from the phase shift taking into account the wavelength of the modulation and the speed of light. It may further be provided that a reference phase is determined with a second detector having a constant distance (not shown) to determine the phase shift based on a comparison to the reference phase.

The laser rangefinder 1 may comprise a measurement controller 2. The measurement controller 2 in particular assumes control of the laser 3.

Thus, the measurement controller 2 may control an emission of the laser 3 by controlling switching the power on and off, as well as controlling intensity and modulation of a laser beam of the laser 3. This can ensure that the laser beam is transmitted at the correct power and with the correct characteristics.

Furthermore, a laser beam of the laser system 1 may be modulated, for example in the form of pulsed light and/or a continuous wave of variable modulation frequency. Upon receipt by the detector 4 of at least a fraction of the emitted laser light, the measurement controller 2 may process the received signal. This includes, for example, amplification, filtering and conversion of the received analog signal into a digital signal for further analysis, in particular by an analog-digital converter 5. Furthermore, the phase shift between the transmitted signal and the received signal may be measured and optionally compared to the reference phase.

The measurement controller 2 may also periodically perform calibrations to ensure that the measurements are precise. For this purpose, it can monitor a state of the laser 3 and the detector 4 to ensure that they are functioning properly.

In addition, the laser system 1, in particular the laser rangefinder, can comprise an analog-digital converter 5. The analog-digital converter 5 preferably converts analog signals received from the detector 4 into digital signals. In particular, these signals represent an intensity of light transmitted by the laser diode 3. The digital conversion may allow the phase shift between the transmitted signal and the received signal to be analyzed. The digital signals provided by the analog-digital converter 5 may be further filtered, amplified, and processed to reduce noise and improve signal quality.

A digital-analog converter 6 in the laser system 1, or laser rangefinder, in particular, has the task of converting digital control signals into analog signals. These analog signals can be used to precisely control various components of the laser system 1, in particular the laser diode 3. The digital-analog converter 6 preferably generates analog voltages or currents needed to operate and modulate the laser diode 3. This control is critical to the emission of the laser beam with the desired intensity and modulation. By converting digital modulation commands into analog signals, the digital-to-analog converter 6 can control the modulation of the laser beam. This may include pulsed light or a continuous wave of variable modulation frequency. Furthermore, the digital-to-analog converter 6 may convert digital feedback from the measurement controller 2 to analog control signals to continuously adjust the power and stability of the laser diode 3.

The measurement controller 2 preferably generates digital signals based on requirements of the measurement process and feedback from sensors and other components. These digital signals are in particular sent to the digital-analog converter 6. The digital-analog converter 6 preferably converts the received digital signals into analog voltages or currents. These analog signals may then be used to control the laser diode 3 and other analog components.

During each change of a modulation frequency, according to exemplary embodiments, an offset matching the efficiency of the next modulation frequency is preferably loaded and thus the diode current is shifted in advance to match the efficiency. The offsets may be determined by reading a change in the integral part in the unmodulated case. This can either be pre-read in the laboratory and set equally for all laser systems 1 or calibrated on a customized basis in the production department or continuously dynamically determined and adjusted to automatically in the laser system 1.

The above explanation of the embodiments describes the present disclosure solely within the scope of examples. Of course, individual features of the embodiments can be freely combined with one another, if technically feasible, without leaving the scope of the present disclosure.

What is claimed is:

1. A method for adjusting a diode current of a laser system, comprising:
determining a change in an integral part of a control signal of the laser system in an unmodulated laser operation; and
adjusting the diode current of the laser system in a modulated laser operation based on the determined change in the integral part,
wherein the modulated laser operation differs from the unmodulated laser operation in that intensity modulation is performed during light emission in the modulated laser operation.

2. The method according to claim 1, wherein the adjusting is performed specifically for a modulation frequency used in the intensity modulation, by which the light emitted by a laser diode is intensity modulated, and wherein the laser diode is operated by the diode current.

3. The method according to claim 2, wherein:
for at least two modulation frequencies, the intensity modulation is performed and the adjustment is performed specifically for the respective modulation frequency of the at least two modulation frequencies.

4. The method according to claim 1, wherein the determining is performed on a device-specific basis for the laser system.

5. The method according to claim 1, wherein the determining is performed repeatedly during operation of the laser system to dynamically determine the change in the integral part.

6. The method according to claim 1, wherein the adjusting comprises:
determining an offset for an input value of a digital-analog converter of the laser system based on the determined change in the integral part, and
adding the determined offset to a current input value of the digital-analog converter of the laser system to use it as the new input value for the digital-analog converter.

7. The method according to claim 1, wherein the laser system is a laser rangefinder.

8. A computer program, comprising instructions that, when the computer program is executed by a computer, cause the computer to carry out the method according to claim 1.

9. A device for data processing, configured to carry out the method according to claim 1.

10. A computer-readable storage medium, comprising commands which, when executed by a computer, cause said computer to carry out the steps of the method according to claim 1.
